(19) United States
(12) Patent Application Publication
(10) Pub. No.: US 2025/0160105 A1
(43) Pub. Date: May 15, 2025

(54) BIFACIAL POWER GENERATION THIN-FILM SOLAR CELL

(71) Applicant: TAIWAN PEROVSKITE SOLAR CORP., Zhubei City (TW)

(72) Inventors: Han-Tu LIN, Zhubei City (TW); Chih-Hsuan CHAO, Zhubei City (TW)

(21) Appl. No.: 18/390,030

(22) Filed: Dec. 20, 2023

(30) Foreign Application Priority Data
Nov. 15, 2023 (TW) 112144042

(51) Int. Cl. H10K 39/12; H10K 30/88

(52) U.S. Cl. CPC H10K 39/12; H10K 30/88

(57) ABSTRACT

The present invention provides a bifacial power generation thin-film solar cell, which comprises: an upper packaging layer; plural first thin-film solar cell units, below the upper packaging layer; a spacer layer, below the first thin-film solar cell units; plural second thin-film solar cell units, below the spacer layer; and a lower packaging layer, below the second thin-film solar cell units; wherein the first thin-film solar cell units, the spacer layer and the second thin-film solar cell units have plural packaging borders; wherein both the first and second thin-film solar cell units comprise respectively: a first electrode layer; a first carrier transport layer, below the first electrode layer; a light-absorption layer, below the first carrier transport layer; a second carrier transport layer, below the light-absorption layer; and a second electrode layer, below the second carrier transport layer.

### CROSS-REFERENCE TO RELATED APPLICATIONS

This application claims priority to Taiwan Application Serial Number 112144042, filed Nov. 15, 2023, which is herein incorporated by reference in its entirety.

### BACKGROUND

### Technical Field

The present invention is in related to a solar cell, more particularly to a perovskite solar cell.

### Related Art

Among the present technologies of solar cells, even if perovskite-silicon stacked cells are able to generate more electricity per unit area, it is still a big challenge whether the output is enough to provide the energy of the added time and process cost of stacking. The current efficiency of small-area silicon solar cells is 26%, and the efficiency of perovskite-silicon solar cells is 33%, an increase for efficiency is only 7%, so the cost increase cannot exceed 25%. Additionally, perovskite-silicon stacked solar cells do not figure out the problem of high-temperature manufacturing processes for silicon wafer solar cells yet. In the existing technology, if perovskite is simply used as a two-terminal stacked solar cell, there are still many process challenges in the front. For instance, the wet film coating of the second layer of perovskite will dissolve the first layer of perovskite, etc., hence other expensive processes such as atomic vapor deposition (ALD), etc. must be required; or physical vapor deposition is another option but with poor film forming properties. What is more, the double-glass components of silicon solar cells are often used for generating electricity. On the other hand, in case the amount of light emitted is insufficient, such as that the ground reflected light will be red-shifted compared with the solar spectrum in a cloudy day, and it results in less light to be applied.

Furthermore, unlike other types of solar cells, the energy gap of perovskite solar cells can be adjusted, ranging from 1.2 eV to 3.5 eV. This adjustment is mainly achieved by controlling the ionic ratio of perovskite. According to research (Nature Energy, 828-838 (2018)), it is shown that the most suitable energy gap for tandem solar cells is 1.8 eV. Therefore, high-efficiency perovskite solar cells are currently considered the most suitable candidate for silicon tandem solar cells. Certainly, perovskite solar cells can be stacked to each other if the energy gaps are different. The cell with higher energy gap is on a surface that faces the light, and the cell with lower energy gap is on a surface that faces away from the light. In the case of a four-terminal configuration (4-terminal (4T)), this arrangement can increase the power generation efficiency per unit area as well.

Compared with the present technologies, perovskite solar cell belongs to thin-film solar cell; on the contrary, silicon wafer solar cell is with a larger area. Hence, laser applications are adopted to the thin film, that is, a larger thin-film solar cell is transformed to the form of series connection. Please refer to FIG. 1, which illustrates a schematic cross-sectional view of the prior perovskite solar cell. As shown in FIG. 1, two solar cells are in a series connection, and three wirings 104, 106, 108 are cut without overlapping in a manufacturing process. In FIG. 1, a perovskite solar cell 100 is cut to become several solar cells with series connection, that is, every two adjacent solar cell units are cut to form three sections, which are cutting sections 104, 106, 108. The cutting section 104 is for front-side electrode short-circuit cutting, and is a surface facing the light; the cutting section 106 is for series connection channel cutting; and the cutting section 108 is for electrode short-circuit cutting, and is a surface facing away from the light. The series connection channel of the cutting section 106 is fill out with electrode materials for adjacent solar cell units being connected in series. According to FIG. 1, the perovskite solar cell 100 includes a packaging layer 110 (a surface facing the light), a packaging layer 112 (a surface facing away from the light), an electrode 114 (a surface facing the light), an electrode 122 (a surface facing away from the light), a carrier transport layer 116, a light-absorption layer 118, a carrier transport layer 120, an external line 124, and an external line 126. The cutting section 104, cutting section 106, and cutting section 108 are the locations of the so-called cutting stripes. The current travels along a dashed line 128, wherein the cutting section 106 is filled with a conductive layer, typically the same material as the electrode (a surface facing away from the light). It serves as the path through which the current passes, so the size of this cutting line can be optimized, and therefore it results in a striped pattern on the overall module. If the electrode 122 (a surface facing away from the light) adopts transparent conductive materials, such as indium tin oxide (ITO), indium-doped zinc oxide (IZO), etc., then the cutting line is transparent. Thus, the sunlight will pass through most of the area, and it resulting in a waste of light source in this area.

Therefore, the present invention provides a form of thin-film solar cell stacking layer, that is, disposing two layers of thin-film solar cells in a staggered arrangement, in order to let the incident light be not wasted and achieve an effect of visually the modules looking consistent. In addition, two sides of the double-layer thin-film solar cell provided by the present invention are with the effect of light-transmitting, and it will be applied to generate power by reflected light. Further, the present invention is able to adopt a vertical arrangement. Although some light may not be absorbed, an effect of visual design can be achieved as well. Furthermore, the present invention proposes a design of stacked solar cells with a four-terminal configuration (4-terminal) using thin-film solar cells, and it effectively reduces costs, increases the power generation area, and enhances the utilization of reflected light.

As a conclusion, with large-area cutting strips on perovskite solar cells, the visual aesthetics are significant. Therefore, addressing this issue is a matter that people skilled in the art urgently need to consider and figure out.

### SUMMARY

The purpose of the present invention discloses a stacking structure for a bifacial light-transmitting thin-film solar cell, that is, a thin-film solar cell with a higher energy gap (E_{g1}) is on the top, and another thin-film solar cell with a lower energy gap (E_{g2}) is below the thin-film solar cell with a higher energy gap (E_{g1}). Photons will take the following paths separately:

For example, photons (E>E_{g2}) are absorbed by the second thin-film solar cell.

For example, photons (E>E_{g1}) are absorbed by the first thin-film solar cell.

For example, photons (E>E_{g2}) are absorbed by the second thin-film solar cell.

The stacked structure design of the bifacial light-transmitting thin-film solar cell is with the following advantages listed below paragraphs.

Stacking type is adopted to increase power generation efficiency and power generation area. Since the wavelength of scattered light is longer, a solar cell with weak light enhancement or a smaller energy gap disposed below can make the scattered light be more effective.

Due to massproduction, the cost of perovskite thin-film solar cells is lower than the cost of silicon solar cells.

Because the perovskite thin-film solar cell is used as the second thin-film solar cell, it is easier to adjust to a light source suitable for the environment (low light power generation) than a silicon wafer.

The present invention provides a bifacial power generation thin-film solar cell, which comprises: an upper packaging layer; a plurality of first thin-film solar cell units, disposed below the upper packaging layer; a spacer layer, disposed below the plurality of first thin-film solar cell units; a plurality of second thin-film solar cell units, disposed below the spacer layer; and a lower packaging layer, disposed below the plurality of second thin-film solar cell units; wherein the first thin-film solar cell units, the spacer layer and the second thin-film solar cell units have a plurality of packaging borders; wherein both the first thin-film solar cell unit and the second thin-film solar cell unit comprise respectively: a first electrode layer; a first carrier transport layer, disposed below the first electrode layer; a light-absorption layer, disposed below the first carrier transport layer; a second carrier transport layer, disposed below the light-absorption layer; and a second electrode layer, disposed below the second carrier transport layer; wherein an energy gap of the light-absorption layer of the first thin-film solar cell unit is greater than an energy gap of the light-absorption layer of the second thin-film solar cell unit.

According to one or more embodiments of the present invention, series wirings of the first thin-film solar cell units and component areas of the second thin-film solar cell units are overlapped in a range of 50% to 100%, and a total area of the series wirings of the first thin-film solar cell units is a reference value.

According to one or more embodiments of the present invention, each of the first thin-film solar cell unit or the second thin-film solar cell unit is a rectangular unit, and each of the rectangular units is oriented with two long sides thereof, a direction of each first thin film solar cell unit and each second thin film solar cell unit is configured to be horizontal or vertical.

The present invention provides another embodiment, which is a perovskite solar cell. The perovskite solar cell comprises: an upper thin-film solar cell module; a lower thin-film solar cell module; a spacer layer, disposed in between the upper thin-film solar cell module and the lower thin-film solar cell module; a plurality of packaging borders, disposed on lateral sides of the upper thin-film solar cell module, the spacer layer and the lower thin-film solar cell module, in order to package the upper thin-film solar cell module, the spacer layer and the lower thin-film solar cell module to become the bifacial power generation thin-film solar cell; wherein any of the thin-film solar cell units of the upper thin-film solar cell module or the lower thin-film solar cell module comprises: a first electrode layer; a first carrier transport layer, disposed below the first electrode layer; a light-absorption layer, disposed below the first carrier transport layer; a second carrier transport layer, disposed below the light-absorption layer; and a second electrode layer, disposed below the second carrier transport layer; wherein an energy gap of the light-absorption layer of any of the thin-film solar cell units of the upper thin-film solar cell module is greater than an energy gap of the light-absorption layer of any of the thin-film solar cell units of the lower thin-film solar cell module.

According to one or more embodiments of the present invention, series wirings of any of the thin-film solar cell units of the upper thin-film solar cell module and component areas of any of the thin-film solar cell units of the lower thin-film solar cell module are overlapped in a range of 50% to 100%, and a total area of the series wirings of any of the thin-film solar cell units of the upper thin-film solar cell module is a reference value.

According to one or more embodiments of the present invention, any of the thin-film solar cell units of the upper thin film solar cell module or the lower thin-film solar cell module is a rectangular unit, and each of the rectangular units is oriented with two long sides thereof, a direction of each thin-film solar cell unit of the upper thin-film solar cell module and the lower thin-film solar cell unit is configured to be horizontal or vertical. As a conclusion, the perovskite solar cell provided by the present invention is

able to solve the problem of the visual aesthetics of the perovskite solar cell with large-area cutting strips.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 illustrates a schematic cross-sectional view of the prior perovskite solar cell;

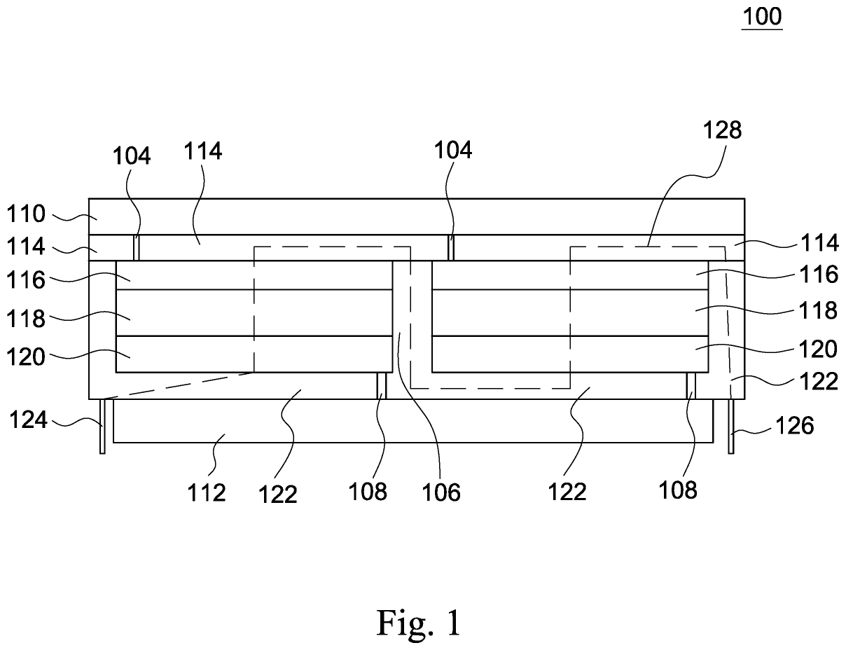

FIG. 2, which illustrates a schematic cross-sectional view of an embodiment of a stacked structure design of the bifacial light-transmitting thin-film solar cell of the present invention;

FIG. 3 illustrates a schematic cross-sectional view of an embodiment of a stacked structure design of the bifacial light-transmitting thin-film solar cell of the present invention; and

FIG. 4 illustrates a schematic cross-sectional view of an embodiment of a stacked structure design of the bifacial light-transmitting thin-film solar cell of the present invention.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Certain terms are used throughout the description and following claims to refer to particular components. As one skilled in the art will appreciate, manufacturers may refer to a component by different names. This document does not intend to distinguish between components that differ in name but function. In the following description and in the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the disclosure. This description is made for the purpose of illustration of the general principles of the disclosure and should not be taken in a limiting sense. The scope of the disclosure is best determined by reference to the appended claims.

Moreover, the terms “include”, “contain”, and any variation thereof are intended to cover a non-exclusive inclusion. Therefore, a process, method, object, or device that includes a series of elements not only includes these elements, but also includes other elements not specified expressly, or may include inherent elements of the process, method, object, or device. If no more limitations are made, an element limited by “include a/an . . . ” does not exclude other same elements existing in the process, the method, the article, or the device which includes the element.

According to the shortcomings in the structure of perovskite solar cells for existing technologies, the present invention provides a thin-film solar cell design that achieves the effects of increasing power generation efficiency and enhancing aesthetic design.

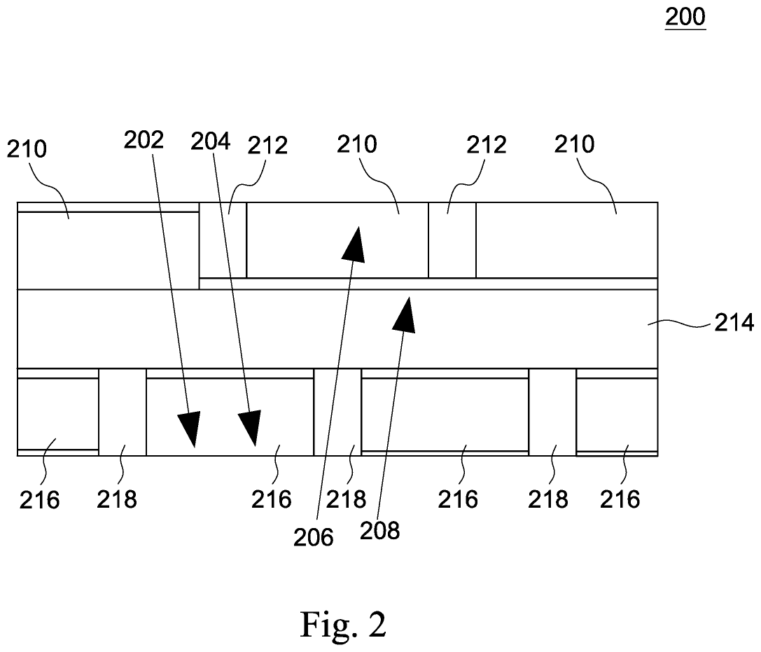

Please refer to FIG. 2, which illustrates a schematic cross-sectional view of an embodiment of a stacked structure design of the bifacial light-transmitting thin-film solar cell of the present invention. As shown in FIG. 2, the stacked structure design of the present invention is as that, a thin-film solar cell with a high energy gap (E_{g1}) is on the top, and a thin-film solar cell with a low energy gap (E_{g2}) is on the bottom. Photons will take the following paths respectively, which are listed below paragraphs.

For instance, High-energy photons (E>E_{g1}) are absorbed by the first thin-film solar cell, and low-energy photons (E_{g1}>E>E_{g2}) are absorbed by the second thin-film solar cell.

For example, photons (E>E_{g2}) are absorbed by the second thin-film solar cell.

For example, photons (E>E_{g1}) are absorbed by the first thin-film solar cell.

Such as, photons (E>E_{g2}) are absorbed by the second thin-film solar cell.

The stacked structure design of the bifacial light-transmitting thin-film solar cell is with the following advantages listed below paragraphs.

Stacking type is adopted to increase power generation efficiency and power generation area. Since the wavelength of scattered light is longer, a solar cell with weak light enhancement or a smaller energy gap disposed below can make the scattered light be more effective.

Due to massproduction, the cost of perovskite thin-film solar cells is lower than the cost of silicon solar cells.

Because the perovskite thin-film solar cell is used as the second thin-film solar cell, it is easier to adjust to a light source suitable for the environment (low light power generation) than a silicon wafer.

As shown in FIG. 2, a perovskite solar cell 200 includes a first thin-film solar cell, constructed by a solar cell module 210 and series wirings 212, a spacer layer 214 and a second thin-film solar cell, constructed by a solar cell module 216 and a gap 218. For the embodiment, the series wirings 212 are arranged interactively. Hence, an incident light goes through an incident location 202 and another incident location 204 to the perovskite solar cell 200, and a reflected light goes into the perovskite solar cell 200 via an incident location 206 and another incident location 208.

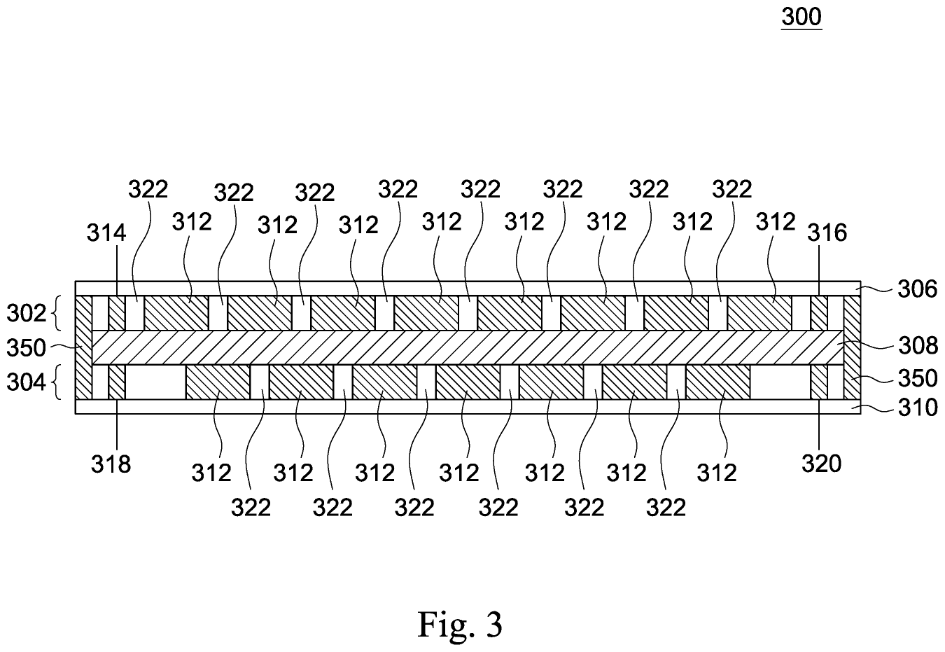

With reference to FIG. 3, which illustrates a schematic cross-sectional view of an embodiment of a stacked structure design of the bifacial light-transmitting thin-film solar cell of the present invention. According to FIG. 3, the embodiment of the bifacial light-transmitting thin-film solar cell 300 includes two thin-film solar cell modules, which are an upper thin-film solar cell module 302 and a lower thin-film solar cell module 304. Besides, the bifacial light-transmitting thin-film solar cell 300 further includes a spacer layer 308, a plurality of packaging borders 350, a plurality of external lines 314, 316, 318, 320. For the embodiment, the packaging borders 350 touch onto an upper packaging layer 306, the spacer layer 308 and a lower packaging layer 310. Therefore, by combining the upper thin-film solar cell module 302 and the lower thin-film solar cell module 304, the bifacial light-transmitting thin film solar cell 300 is packaged.

As shown in FIG. 3, the upper thin-film solar cell module 302 includes the upper packaging layer 306, a plurality of solar cell units 312 and a plurality of series wirings 322;

respectively, the lower thin-film solar cell module 304 includes the lower packaging layer 310, a plurality of solar cell units 312 and a plurality of series wirings 322. As for the embodiment, the series wirings 322 of the upper thin-film solar cell module 302 and component areas of the lower thin-film solar cell module 304 are overlapped.

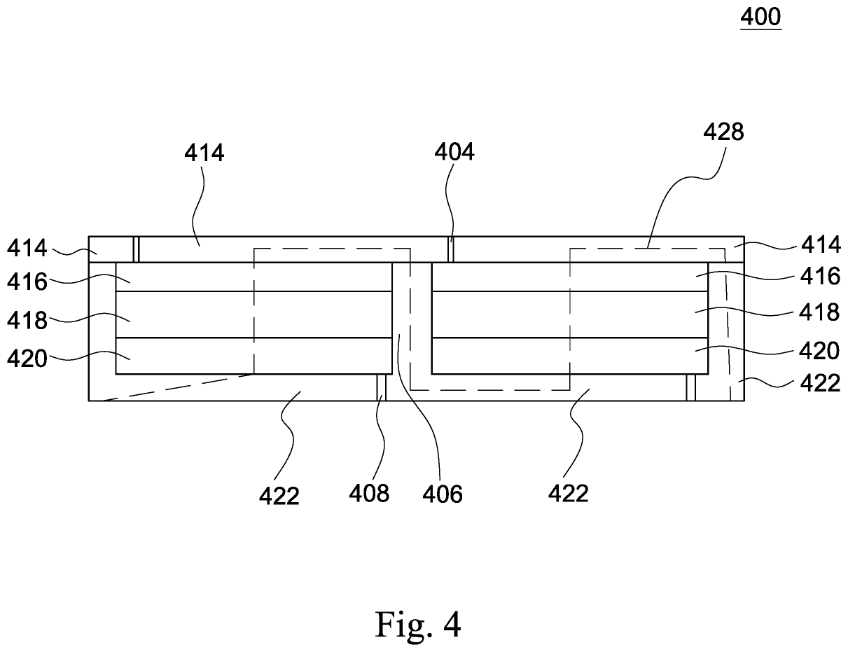

As to FIG. 4, which illustrates a schematic cross-sectional view of an embodiment of a stacked structure design of the bifacial light-transmitting thin-film solar cell of the present invention. Accordingly, a bifacial light-transmitting thin-film solar cell 400 has at least a first electrode 414 (a surface facing the light), a first carrier transport layer 416 (a surface facing the light), a light-absorption layer 418, a second carrier transport layer 420 (a surface facing away from the light), and a second electrode 422 (a surface facing away from the light) from top to bottom. Based on FIG. 3, an energy gap of a material of the light-absorption layer of the upper thin-film solar cell module 302 is greater than an energy gap of a material of the light-absorption layer of the lower thin-film solar cell module 304. As shown in FIG. 4, a perovskite solar cell 400 includes several cutting areas 404, 406, 408, the first electrode 414, the first carrier transport layer 416, the light-absorption layer 418, the second carrier transport layer 420, the second electrode 422, and the external lines (not shown in figure). Again, FIG. 4 shows that the current follows the dashed line 428.

In accordance with FIG. 3, in an embodiment, the upper packaging layer 306 and the lower packaging layer 307 are all made by transparent glass. Transparent glass can be alkali-free glass, soda-lime glass, etc., but not limited thereto. Again, the upper packaging layer 306 and the lower packaging layer 307 can be transparent plastic etc. as well.

Referring to FIG. 3, in another embodiment, the material of the electrodes of the two solar cell modules 302,304 is metal oxides or metals, but with no limitations thereto, such as fluorine-doped tin oxide (FTO), indium tin oxide (ITO), indium zinc oxide (Indium Zinc Oxide, IZO), aluminum-doped zinc oxide (Al doped-ZnO, AZO)), indium tungsten oxide (IWO), indium molybdenum oxide (IMO), zinc tin oxide (ZTO), indium titanium oxide (ITiO), hydride-doped indium oxide (indium oxide hydrate, IOH) or antimony tin oxide (ATO), copper (Cu), nickel (Ni), molybdenum (Mo), silver (Ag), gold (Au) and other metals or their alloys one or more materials in a group.

With relation to FIG. 4, the light-absorption layer 418 is made by perovskite, which is a three-dimensional form, and represented by the chemical formula ABX3, wherein the position A includes one or more monovalent cations selected from the group consisting of formamidinium, methylammonium, cesium (Cs), and rubidium (Rb); the position B includes one or more divalent cations selected from the group consisting of lead (Pb) and tin (Sn); the position X includes one or more monovalent anions selected from the group consisting of chlorine (Cl), bromine (Br), and iodine (I), but in practice, the perovskite is not limited to three-dimensional crystalline form, and can also be in the form of quasi-two-dimensional, two-dimensional, one-dimensional or quantum dots.

Again, as for FIG. 4, in one embodiment, if light through a bifacial light-transmitting thin-film solar cell 400, such as perovskite solar cell, is a formal structure (n-i-p structure), the first carrier transport layer 416 is an electron transport layer, the second carrier transport layer 420 is a hole transport layer. For another embodiment, If the bifacial light-transmitting thin-film solar cell 400, such as perovskite solar cell, is a reverse structure (p-i-n structure), the first carrier transport layer 416 is a hole transport layer, the second carrier transport layer 420 is an electron transport layer.

Please refer to FIG. 4 again, in one embodiment of the present invention, the materials of the electron transport layer are n-type semiconductors, including but not limited to titanium dioxide (TiO₂), tin dioxide (SnO₂), phenyl carbon 61-butyric acid methyl ester ([6,6]-phenyl-C61-butyric acid methyl ester, PCBM), zinc oxide (ZnO), vanadium pentoxide (V₂O₅), zinc stannate (Zn₂SnO₄), fullerene (C60), fullerene C70 or fullerene derivatives, etc.

For one embodiment, the hole transport layer is a p-type semiconductor, and includes but not limited to Nickel oxide (NiO), molybdenum trioxide (MoO₃), copper (I) oxide, Cu₂O), copper iodide (Copper (I) iodide, CuI), copper phthalocyanine (CuPc), copper (I) thiocyanate (CuSCN), redox graphene, poly[bis(4-phenyl) (2,4,6-trimethylphenyl)amine](poly[bis(4-phenyl) (2,4,6-trimethylphenyl)amine, PTAA), 2,2′,7,7′-tetrakis[N,N-bis(4-methoxyphenyl)amino]-9, 9′-spirobifluorene (2,2′,7,7′-tetrakis[N,N-di (4-methoxyphenyl)amino]-9,9′-spirobifluorene, Spiro-OMeTAD), polydioxyethylthiophene:Poly(3,4-ethylenedioxythiophene) polystyrene sulfonate, PEDOT:PSS), poly[bis(4-phenyl) (4-butylphenyl)amine (Poly [N,N′-bis(4-butylphenyl)-N,N′-bis (phenyl)-benzidine], Poly-TPD) or polyvinylcarbazole (Poly (N-vinylcarbazole), PVK).

Please refer to FIG. 3 again, in one of the embodiments of the present invention, the upper packaging layer 306 and the lower packaging layer 310 are made of soda-lime glass, the spacer layer 308 is made of soda-lime glass and POE material, and the packaging border 350 is made of butyl glue. In addition, for the upper thin-film solar cell module 302 and the lower thin-film solar cell module 304, the first electrode 414 (a surface facing the light) is made of FTO, the first carrier transport layer 416 (a surface facing the light) is made of titanium dioxide, the second carrier transport layer 420 (a surface facing away from the light) is all made of spiro-OMeTAD, and the second electrode 422 (a surface facing away from the light) is made of IZO. The composition of the light-absorption layer of the upper thin-film solar cell module 302 is MAPbBrI₂, and the composition of the light-absorption layer of the lower thin-film solar cell module 304 is MAPbI₃. The specific preparation methods of the above embodiments are as follows. As shown in FIG. 3 and FIG. 4, two FTO glasses are to be the upper packaging layer 306 and the lower packaging layer 310; the upper packaging layer 306 is to be a substrate of the upper thin-film solar cell module 302; and the lower packaging layer 310 is to be a substrate of the lower thin-film solar cell module 304. The electrode (a surface facing away from the light) and the spacer layer 308 of the upper thin-film solar cell module 302 (called a first module) and the electrode (a surface facing the light) of the lower thin-film solar cell module 304 (called a second module) fabricate the main components of the bifacial light-transmitting thin-film solar cell 300. For further discussions, in one embodiment of the present invention, the light-receiving surface of the first module with high energy gap is regarded as the surface facing the light, and the light-receiving surface of the second module is regarded as the surface facing away from the light. Therefore, the upper packaging layer 306 is the surface facing the light. The arrangement order, from top to bottom, of the upper thin-film solar cell module 302 (called the first module) is the electrode 414 (a surface facing the light), the carrier transport layer 416, a perovskite layer, the carrier transport layer 420, and the electrode 422 (a surface facing away from the light); on the contrary, the lower thin-film solar cell module 304 (called the second module) is fabricated by the arrangement order, from bottom to top, of the electrode 422 (a surface facing away from the light), the carrier transport layer 420, the perovskite layer, the carrier transport 416, and the electrode 414 (a surface facing the light).

Hence, the spacer layer 308 is installed in between the electrode 422 (a surface facing away from the light) of the first module and the electrode (a surface facing the light) 414 of the second module. Then, one of the stripes is laser etched individually, TiO₂ is sputtered and nano-TiO₂ is slit-coated on the two modules and annealed to 550° C. Continuously, the perovskite precursor solution is slit-coated on TiO₂, and then vacuum annealed to 120° C. to form a light-absorption layer. The spiro-OMeTAD precursor is slit-coated on the light-absorption layer, and then another stripe is laser etched (that is, the location of the subsequent cutting line), then IZO is sputtered, and finally another stripe is laser etched. There is no difference in the manufacturing process between the two modules, only the composition of the precursor of the light-absorption layer is different. Finally, the first module is placed on a POE film, the POE film is placed on the second module, and the POE film is placed on a soda-lime glass. The cutting line of the first module must be partially set on top of the power generation part. Thereupon the modules are laminated.

Although the present disclosure is disclosed in the foregoing embodiments, it is not intended to limit the present disclosure. Changes and modifications made without departing from the spirit and scope of the present disclosure belong to the scope of the claims of the present disclosure. The scope of protection of the present disclosure should be construed based on the following claims.

What is claimed is:

1. A bifacial power generation thin-film solar cell comprising:
an upper packaging layer (306);
a plurality of first thin-film solar cell units, disposed below the upper packaging layer (306);
a spacer layer (308), disposed below the plurality of first thin-film solar cell units;
a plurality of second thin-film solar cell units, disposed below the spacer layer (308); and
a lower packaging layer (310), disposed below the plurality of second thin-film solar cell units;
wherein the first thin-film solar cell units, the spacer layer (308) and the second thin-film solar cell units have a plurality of packaging borders (350);
wherein both the first thin-film solar cell unit and the second thin-film solar cell unit comprise respectively:
a first electrode layer (414);
a first carrier transport layer (416), disposed below the first electrode layer (414);
a light-absorption layer (418), disposed below the first carrier transport layer (416);
a second carrier transport layer (420), disposed below the light-absorption layer (418); and
a second electrode layer (422), disposed below the second carrier transport layer (420);
wherein an energy gap of the light-absorption layer of the first thin-film solar cell unit is greater than an energy gap of the light-absorption layer of the second thin-film solar cell unit.

2. The bifacial power generation thin-film solar cell according to claim 1, wherein series wirings (322) of the first thin-film solar cell units (312) and component areas of the second thin-film solar cell units (312) are overlapped in a range of 50% to 100%, a total area of the series wirings (322) of the first thin-film solar cell units (312) being a reference value.

3. The bifacial power generation thin-film solar cell according to claim 1, wherein each of the first thin-film solar cell unit (312) or the second thin-film solar cell unit (312) is a rectangular unit, and each of the rectangular units is oriented with two long sides thereof, a direction of each first thin film solar cell unit (312) and each second thin film solar cell unit (312) is configured to be horizontal or vertical.

4. A bifacial power generation thin-film solar cell comprising:
an upper thin-film solar cell module (302);
a lower thin-film solar cell module (304);
a spacer layer (308), disposed in between the upper thin-film solar cell module (302) and the lower thin-film solar cell module (304);
a plurality of packaging borders (350), disposed on lateral sides of the upper thin-film solar cell module (302), the spacer layer (308) and the lower thin-film solar cell module (304), in order to package the upper thin-film solar cell module (302), the spacer layer (308) and the lower thin-film solar cell module (304) to become the bifacial power generation thin-film solar cell;
wherein any of the thin-film solar cell units (312) of the upper thin-film solar cell module (302) or the lower thin-film solar cell module (304) comprises:
a first electrode layer (414);
a first carrier transport layer (416), disposed below the first electrode layer (414);
a light-absorption layer (418), disposed below the first carrier transport layer (416);
a second carrier transport layer (420), disposed below the light-absorption layer (418); and
a second electrode layer (422), disposed below the second carrier transport layer (420);
wherein an energy gap of the light-absorption layer (418) of any of the thin-film solar cell units (312) of the upper thin-film solar cell module (302) is greater than an energy gap of the light-absorption layer (418) of any of the thin-film solar cell units (312) of the lower thin-film solar cell module (312).

5. The bifacial power generation thin-film solar cell according to claim 4, wherein series wirings (322) of any of the thin-film solar cell units (312) of the upper thin-film solar cell module (302) and component areas of any of the thin-film solar cell units (312) of the lower thin-film solar cell module (304) are overlapped in a range of 50% to 100%, a total area of the series wirings (322) of any of the thin-film solar cell units (312) of the upper thin-film solar cell module (302) being a reference value.

6. The bifacial power generation thin-film solar cell according to claim 4, wherein any of the thin-film solar cell units (312) of the upper thin film solar cell module (302) or the lower thin-film solar cell module (304) is a rectangular unit, and each of the rectangular units is oriented with two long sides thereof, a direction of each thin-film solar cell unit (312) of the upper thin-film solar cell module (302) and the lower thin-film solar cell unit (304) is configured to be horizontal or vertical.
